(19) United States
(12) Patent Application Publication
(10) Pub. No.: US 2025/0105093 A1
(43) Pub. Date: Mar. 27, 2025

(54) COOLING STRUCTURE AND METHOD FOR SEMICONDUCTOR DEVICE

(71) Applicant: SAMSUNG ELECTRONICS CO., LTD., Suwon-si (KR)

(72) Inventors: Daehyuk SON, Suwon-si (KR); Sungchan KANG, Suwon-si (KR); Dongkyun KIM, Suwon-si (KR); Hotaik LEE, Suwon-si (KR); Seogwoo HONG, Suwon-si (KR)

(73) Assignee: SAMSUNG ELECTRONICS CO., LTD., Suwon-si (KR)

(21) Appl. No.: 18/616,721

(22) Filed: Mar. 26, 2024

(30) Foreign Application Priority Data
Sep. 27, 2023 (KR) 10-2023-0130467

(51) Int. Cl. H01L 23/427

(52) U.S. Cl. CPC H01L 23/427

(57) ABSTRACT

A semiconductor device may include: a semiconductor chip may include a heat radiation part; a pressure chamber formed on the heat radiation part, wherein the pressure chamber is configured to contain coolant such that an internal pressure in the pressure chamber increases as the coolant absorbs heat from the heat radiation part, and the coolant is ejected in a first direction away from the heat radiation part as the internal pressure of the pressure chamber increases; and a cooling channel providing a flow path configured such that the coolant ejected from the pressure chamber flows through the flow path and back into the pressure chamber.

### CROSS-REFERENCE TO RELATED APPLICATION

This application claims priority to Korean Patent Application No. 10-2023-0130467, filed on Sep. 27, 2023, in the Korean Intellectual Property Office, the disclosure of which is incorporated by reference herein in its entirety.

### BACKGROUND

### 1. Field

The disclosure relates to a semiconductor device.

### 2. Description of the Related Art

In order to remove heat generated from electronic devices, air cooling devices have mainly been used. As the power density of electronic devices has increased, the use of liquid cooling devices has increased to cope with higher heat generation. Moreover, in the case of data centers, interest in efficient next-generation cooling methods such as liquid cooling devices is gradually increasing to reduce power usage. Liquid cooling methods may be divided into single-phase liquid cooling methods (without a phase change of a coolant) and two-phase liquid cooling methods (involving a phase change of coolant), depending on the temperature range of the part where heat is generated. The two-phase cooling method is capable of treating a higher range of calorific values than the single-phase cooling method.

### SUMMARY

Example embodiments provide a semiconductor device employing a two-phase cooling structure.

Example embodiments provide a semiconductor device including a pressure chamber capable of causing a flow of a coolant in a cooling channel.

Additional aspects will be set forth in part in the description which follows and, in part, will be apparent from the description, or may be learned by practice of the presented embodiments of the disclosure.

According to an aspect of the disclosure, a semiconductor device may include: a semiconductor chip may include a heat radiation part; a pressure chamber formed on the heat radiation part, wherein the pressure chamber is configured to contain coolant such that an internal pressure in the pressure chamber increases as the coolant absorbs heat from the heat radiation part, and the coolant is ejected in a first direction away from the heat radiation part as the internal pressure of the pressure chamber increases; and a cooling channel providing a flow path configured such that the coolant ejected from the pressure chamber flows through the flow path and back into the pressure chamber.

The pressure chamber may include a coolant ejection part and a coolant inlet that define at least a part of the cooling channel.

The cooling channel may be configured to connect the coolant ejection part and the coolant inlet to each other in order to enable the coolant to circulate within the semiconductor device.

The coolant ejection part may be configured to eject the coolant in a direction perpendicular to the semiconductor chip.

The coolant ejection part may be disposed on an end of the pressure chamber furthest from the heat radiation part in the first direction.

The coolant ejection part may include a nozzle structure.

The coolant ejection part may include a protruding structure protruding in the first direction.

The coolant ejection part may include two or more coolant ejection parts.

An area where the coolant flows in the coolant ejection part may be larger than an area where the coolant flows in the coolant inlet.

The coolant inlet may be arranged so as to allow the coolant to be introduced in a second direction crossing the first direction.

The coolant inlet may be disposed adjacent to the heat radiation part on a side of the pressure chamber parallel to the first direction.

The cooling channel may include an inclined structure connected to the coolant inlet.

The cooling channel may include a backflow prevention structure preventing the coolant from exiting the pressure chamber through the coolant inlet.

The backflow prevention structure may include a flap valve configured to enable opening and closing of the coolant inlet.

The semiconductor device further may include: a liquid coolant for cooling the semiconductor chip. A volume of the liquid coolant may fill a space from at least the heat radiation part to an end of the coolant inlet furthest from the heat radiation part in the first direction within the pressure chamber.

The volume of the liquid coolant may fill at least an inside of the pressure chamber.

The liquid coolant may be configured to increase the internal pressure in the pressure chamber by changing a phase of the liquid coolant into a gaseous phase as the heat radiation part absorbs heat.

The coolant ejection part may be configured to eject gaseous coolant as the internal pressure of the pressure chamber increases.

The heat radiation part may include a fine pattern configured to generate a capillary pressure causing a flow of the coolant on at least a part of a surface of the heat radiation part.

The fine pattern may be configured to induce the flow of the coolant toward a center of the pressure chamber.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor device according to one or more embodiments;

FIG. 2 is a top perspective view of a channel frame according to one or more embodiments;

FIG. 3 is a bottom perspective view of a channel frame according to one or more embodiments;

FIG. 4 is a cross-sectional view of a semiconductor device according to one or more embodiments;

FIG. 5 is a bottom perspective view of a channel frame of the semiconductor device of FIG. 4 according to one or more embodiments;

FIG. 6 is a cross-sectional view of a semiconductor device according to one or more embodiments;

FIG. 7A is a top perspective view of a channel frame according to one or more embodiments;

FIG. 7B is a top perspective view of a channel frame according to one or more embodiments;

FIG. 8 is a cross-sectional view of a semiconductor device according to one or more embodiments;

FIG. 9A is a top perspective view of a channel frame according to one or more embodiments;

FIG. 9B is a top perspective view of a channel frame according to one or more embodiments;

FIG. 10 is a cross-sectional view of a semiconductor device according to one or more embodiments;

FIG. 11 is a cross-sectional view of a semiconductor device according to one or more embodiments;

FIG. 12 is a cross-sectional view of a semiconductor device according to one or more embodiments;

FIG. 13 is a cross-sectional view of a semiconductor device according to one or more embodiments;

FIG. 14A is a perspective view of a backflow prevention structure according to one or more embodiments; and

FIG. 14B is a perspective view of a backflow prevention structure according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. In the following drawings, the same reference numerals refer to the same components, and the size of each component in the drawings may be exaggerated for clarity and convenience of explanation. Meanwhile, the embodiments described below are merely exemplary, and various modifications are possible from these embodiments. In the following, what is described as “upper” or “on” may include not only those directly above, below, left, and right, but also those on top, bottom, left/right in non-contact. A singular expression includes plural expressions, unless the context clearly indicates otherwise. In addition, if a part “includes” a component, it means that it may contain more other components, rather than excluding other components, unless specifically opposed. The use of the term “above” and similar indicative terms may correspond to both singular and plural. If there is no explicit order or contrary description of the steps that make up the method, these steps may be performed in an appropriate order, and are not necessarily limited to the order described. Elements described as “modules” or “part” may be physically implemented by analog and/or digital circuits including one or more of a logic gate, an integrated circuit, a microprocessor, a microcontroller, a memory circuit, a passive electronic component, an active electronic component, and the like. The connection or connection members of the lines between the components shown in the drawing exemplarily represent functional and/or physical or circuit connections; in real devices, they may be represented as replaceable or additional various functional connections, physical connections, or circuit connections. The use of all examples or exemplary terms is simply to describe technical ideas in detail, and the scope is not limited by these examples or the exemplary terms, unless limited by the claims.

An efficient cooling system is useful to solve the cooling problem(s) that has been a factor limiting the performance of electronic devices including semiconductor chips. In the case of semiconductor devices with high performance computing (HPC) fields and stacked three-dimensional semiconductor chips, there is a desire for a cooling system capable of responding to an increase in power density and an increase in the amount of heat generated due to high integration. In order to meet this demand, a two-phase cooling system capable of using latent heat according to the evaporation of a coolant may be applied to the semiconductor device. Two-phase cooling methods include immersion cooling, spray cooling, jet impingement cooling, and the like. In the disclosure, embodiments of a semiconductor device using a two-phase cooling system will be described. However, the two-phase cooling system may not necessarily be applied to the semiconductor device described below. Hereinafter, a diagram for assisting in the description of a semiconductor device is merely a conceptual diagram, and there may be differences in size and ratio from the actual configuration of the semiconductor device. Hereinafter, a semiconductor device according to one or more embodiments will be described.

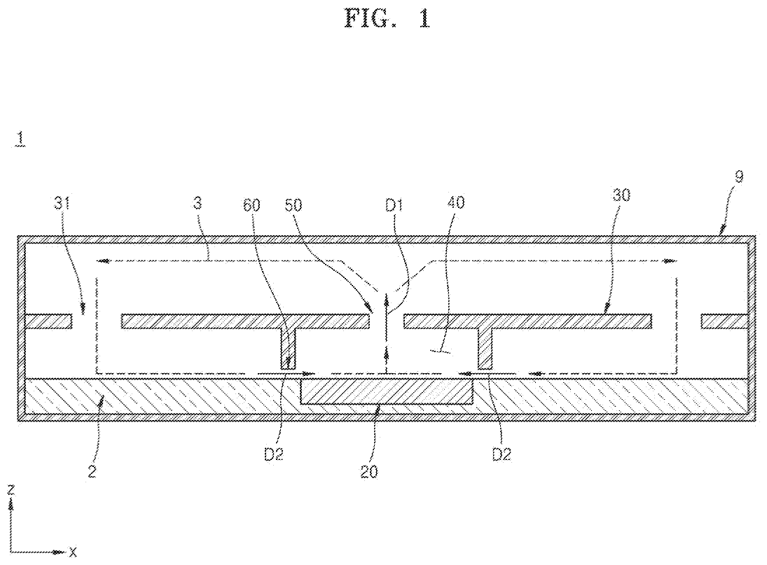

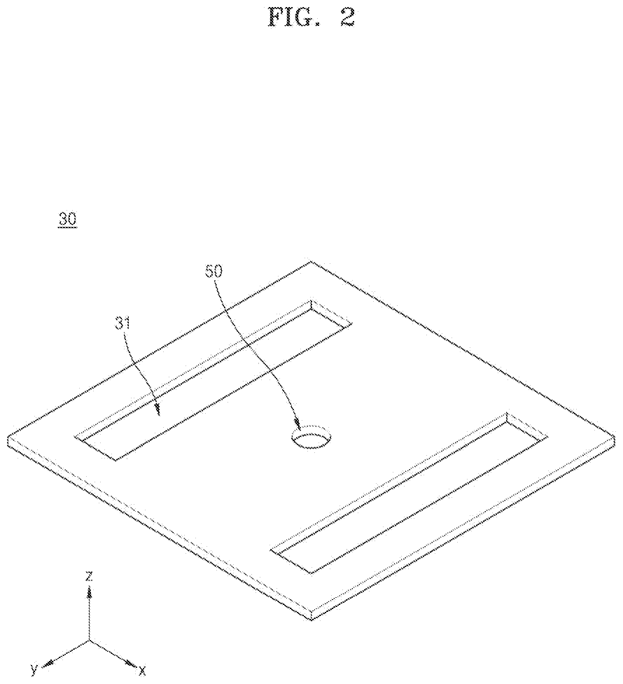

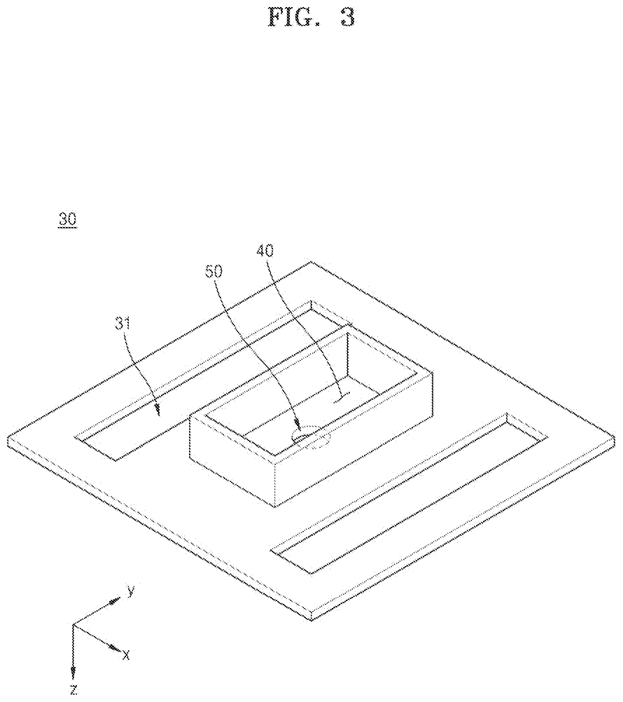

FIG. 1 is a cross-sectional view of a semiconductor device 1 according to one or more embodiments. FIG. 2 is a top perspective view of a channel frame 30 according to one or more embodiments. FIG. 3 is a bottom perspective view of a channel frame 30 according to one or more embodiments.

Referring to FIGS. 1 to 3, the semiconductor device 1 according to one or more embodiments may include a semiconductor chip 2.

The semiconductor chip 2 may be a chip including various semiconductor integrated circuits. For example, the semiconductor chip 2 may be a memory chip with a memory integrated circuit, a logic chip with a logic integrated circuit, a central processing unit (CPU) chip, a graphic processing unit (GPU) chip, an application specific integrated circuit (ASIC) chip, or the like. To implement a semiconductor device 1 of a small form factor, the semiconductor chip 2 may include a wafer-level semiconductor integrated circuit. The semiconductor chip 2 may generate heat when receiving power or while operating. The semiconductor chip 2 may include a heat radiation part 20. The heat radiation part 20 may be disposed on at least a portion of the surface of the semiconductor chip 2. The heat radiation part 20 may be a portion where heat generation of the semiconductor chip 2 is concentrated. The heat radiation part 20 may be a hot spot. When cooling is provided to the heat radiation part 20 of the semiconductor chip 2, the performance of the semiconductor chip 2 may be improved. However, the relationship between the cooling and the arrangement of the heat radiation part 20 and the semiconductor chip 2 is not limited to the above description.

The coolant may cool the semiconductor chip 2 inside the semiconductor device 1 according to one or more embodiments. The semiconductor chip 2 may be provided with cooling using coolant. The coolant may cool the heat radiation part 20 in the semiconductor device 1. The coolant may provide cooling to the heat radiation part 20. The coolant may provide cooling to the heat radiation part 20 through phase change. However, the cooling provided by the coolant to the semiconductor chip 2 or the semiconductor device 1 is not limited to the above description.

The semiconductor device 1 according to one or more embodiments may include a cooling channel 3. At least a portion of the cooling channel 3 may be disposed on the semiconductor chip 2. At least a part of the cooling channel 3 may be disposed on the heat radiation part 20. The cooling channel 3 may provide cooling to the semiconductor chip 2. The cooling channel 3 may provide cooling to the heat radiation part 20. The cooling channel 3 may provide a flow path through which a coolant may flow in the semiconductor device 1. The cooling channel 3 may provide a flow path through which a coolant for absorbing heat generated during the operation of the semiconductor chip 2 may flow. The coolant can be circulated in the cooling channel 3. However, the arrangement of the cooling channels 3 and the relationship between the cooling channel and the coolant are not limited to the above description.

The semiconductor device 1 according to one or more embodiments may include a channel frame 30. The channel frame 30 may be disposed on the semiconductor chip 2. The channel frame 30 may be disposed on the heat radiation part 20. The channel frame 30 may define at least a portion of the cooling channel 3. The channel frame 30 may define the degree of freedom in which the coolant may flow in the cooling channel 3.

The semiconductor device 1 according to one or more embodiments may include a housing 9. The housing 9 may constitute an exterior of the semiconductor device 1. The housing 9 may accommodate the semiconductor chip 2 and the channel frame 30. The housing 9 may support the semiconductor chip 2 and the channel frame 30. The semiconductor chip 2 and the channel frame 30 may be supported by the housing 9. The cooling channel 3 may be disposed within the housing 9. The housing 9 may be a packaging of the semiconductor device 1. However, the function and the role of the housing 9 are not limited to the above description.

The semiconductor device 1 according to one or more embodiments may include a pressure chamber 40. The cooling channel 3 may include a pressure chamber 40. At least a portion of the channel frame 30 may define the pressure chamber 40. The pressure chamber 40 may be disposed on the heat radiation part 20. At least a portion of the pressure chamber 40 may be disposed on the heat radiation part 20. The pressure chamber 40 may be a portion with a high pressure in the cooling channel 3. The pressure chamber 40 and cooling channel 3 may contain the coolant. However, the arrangement of the pressure chamber 40 and the internal pressure are not limited to the above description.

In the semiconductor device 1 according to one or more embodiments, the coolant may cool the heat radiation part 20 in the pressure chamber 40. The coolant may receive the heat from the heat radiation part 20 in the pressure chamber 40. When the coolant receives the heat from the heat radiation part 20, the coolant may undergo a phase change. When liquid coolant receives heat from the heat radiation part 20, the phase may change into gaseous coolant. When the liquid coolant phase-changes into a gaseous coolant in the pressure chamber 40, the internal pressure of the pressure chamber 40 may increase. The pressure chamber 40 may be configured such that its internal pressure increases as the coolant absorbs heat from the heat radiation part 20. However, the relationship between the pressure of the pressure chamber 40 and the phase change of the coolant is not limited to the above description.

On the other hand, when the pressure inside the pressure chamber 40 increases, the coolant in the pressure chamber 40 may be ejected out of the pressure chamber 40.

The pressure chamber 40 according to one or more embodiments may include a coolant ejection part 50. The pressure chamber 40 may include a coolant ejection part 50 configured to eject the coolant as the internal pressure increases. The coolant ejection part 50 may eject the coolant to the outside of the pressure chamber 40 as the internal pressure of the pressure chamber 40 increases. The coolant ejection part 50 may define at least a portion of the cooling channel 3. The coolant ejection part 50 may be a portion through which the coolant inside the pressure channel is ejected out of the pressure channel. The coolant ejection part 50 may be disposed on the channel frame 30. The coolant ejection part 50 may be disposed on an upper surface of the channel frame 30. The coolant ejection part 50 may be disposed at an upper end of the pressure chamber 40. A direction spaced apart from the heat radiation part 20 may be a first direction D1. Thus, the coolant ejection part 50 may be disposed at an end of the pressure chamber 40 furthest from the heat radiation part 20 in the first direction D1. The coolant ejection part 50 may be disposed in at least a part of the cooling channel 3. The coolant may be ejected to the outside of the pressure chamber 40 through the coolant ejection part 50. However, the way of ejecting the coolant to the outside of the pressure chamber 40 through the coolant ejection part 50 is not limited to the above description.

The pressure chamber 40 according to one or more embodiments may include a coolant inlet 60. The coolant inlet 60 may define at least a portion of the cooling channel 3. The coolant inlet 60 may be a portion through which the coolant is introduced into the pressure channel. The coolant may be introduced into the pressure chamber 40 through the coolant inlet 60. Thus, the cooling channel 3 may provide a flow path configured such that the coolant ejected from the pressure chamber 40 flows through the flow path and back into the pressure chamber 40. The coolant inlet 60 may be disposed on the channel frame 30. The coolant inlet 60 may be disposed on a side surface of the channel frame 30. The coolant inlet 60 may be disposed on a side surface of the pressure chamber 40. The coolant inlet 60 may be disposed on a lower part of the side of the channel frame 30. In other words, the coolant inlet 60 may be disposed adjacent to the heat radiation part 20 on a side of the pressure chamber 40 parallel to the first direction D1. The coolant inlet 60 may be disposed on a lower part of the side of the pressure chamber 40. The coolant inlet 60 may be disposed between the channel frame 30 and the semiconductor chip 2. The coolant inlet 60 may be disposed between the channel frame 30 and the heat radiation part 20. A plurality of coolant inlets 60 may be provided. However, the arrangement of the coolant inlet 60 and a way of allowing the coolant to flows into the pressure chamber 40 are not limited to the above description.

The coolant ejection part 50 according to one or more embodiments may eject the coolant in a direction spaced apart from the heat radiation part 20. As the internal pressure increases, the pressure chamber 40 may eject the coolant in a direction spaced apart from the heat radiation part 20. A direction in which the coolant is ejected from the coolant ejection part 50 may be a first direction D1. The coolant ejection part 50 may eject the coolant inside the pressure chamber 40 in the first direction D1. The coolant may be discharged from the inside of the pressure chamber 40 in the first direction D1 through the coolant ejection part 50. The first direction D1 may be a direction parallel to the z-axis. The first direction D1 may be a direction perpendicular to the surface of the semiconductor chip 2. The coolant ejection part 50 may eject the coolant in a direction perpendicular to the semiconductor chip 2. The first surface may be perpendicular to the surface of the heat radiation part 20. The coolant ejection part 50 may eject the coolant in a direction perpendicular to the heat radiation part 20. The first direction D1 may be a direction toward the outside of the pressure chamber 40 from the inside of the pressure chamber 40. However, the above description for the direction indicated by the first direction D1 is only an exemplary description, and the direction indicated by the first direction D1 is not limited to the above description.

Meanwhile, when the coolant in the pressure chamber 40 is ejected out of the pressure chamber 40, the pressure in the pressure chamber 40 may be lowered. When the pressure of the pressure chamber 40 is lowered, the coolant may be reintroduced into the pressure chamber 40.

The coolant inlet 60 according to one or more embodiments may be disposed to allow the coolant to flow in the second direction D2 in the pressure chamber 40. The coolant may be introduced from the outside of the pressure chamber 40 toward the inside of the pressure chamber 40 in the second direction D2. The second direction D2 may be a direction intersecting the first direction D1. The second direction D2 may be a direction parallel to the x-axis. The second direction D2 may be a direction perpendicular to the first direction D1. The second direction D2 may be a direction parallel to the upper surface of the semiconductor chip 2. The second direction D2 may be a direction parallel to the upper surface of the heat radiation part 20. The second direction D2 may be a direction from the outside of the pressure chamber 40 toward the inside of the pressure chamber 40. The directions in which the coolant flows from a plurality of coolant inlets 60 toward the pressure chamber 40 may be different to each other. A plurality of coolant inlets 60 may be provided. However, the above description for the direction indicated by the second direction D2 is only an exemplary description, and the direction indicated by the second direction D2 is not limited to the above description.

The cooling channel 3 according to one or more embodiments may have a coolant circulation structure. The cooling channel 3 may be configured to circulate a coolant in the semiconductor device 1. The cooling channel 3 may connect the coolant ejection part 50 and the coolant inlet 60 in order to let the coolant circulate in the semiconductor device 1. The coolant ejected from the pressure chamber 40 through the coolant ejection part 50 may flow to the coolant inlet 60 through the cooling channel 3. The coolant may have a circulation structure in the semiconductor device 1.

The cooling channel 3 according to one or more embodiments may include a coolant circulation part 31. The coolant circulation part 31 may define at least a part of the cooling channel 3. The coolant circulation part 31 may provide a path through which the coolant ejected through the coolant ejection part 50 flows to the coolant inlet 60. The coolant ejected by the coolant ejection part 50 may flow to the coolant inlet 60 through the coolant circulation part 31. The coolant circulation part 31 may be disposed on the channel frame 30. The coolant circulation part 31 may be disposed on the side of the channel frame 30. There may be a plurality of coolant circulation part 31. However, the arrangement and the function of the coolant circulation part 31 are not limited to the above description.

On the other hand, in order to discharge the coolant from the coolant ejection part 50 as the internal pressure of the pressure chamber 40 changes, the coolant ejection part 50 may have a specific arrangement and/or a specific form. In order to let the coolant flow into the coolant inlet 60 as the internal pressure of the pressure chamber 40 changes, the coolant inlet 60 may have a specific arrangement and/or a specific shape. In order for the coolant to be discharged from the coolant ejection part 50 in the first direction D1, the coolant ejection part 50 and the coolant inlet 60 may be placed at a specific location. In order for the coolant to flow from the coolant inlet 60 to the second direction D2, the coolant ejection part 50 and the coolant inlet 60 may be placed at a specific location. In order for the coolant to be discharged from the coolant ejection part 50 in the first direction D1, the coolant ejection part 50 and the coolant inlet 60 may have a specific shape. In order for the coolant to flow from the coolant inlet 60 to the second direction D2, the coolant ejection part 50 and the coolant inlet 60 may have a specific shape. However, the arrangement and the shape of the coolant ejection part 50 and the coolant inlet 60 are not limited to the above description. According to the embodiment, in order for the coolant to be discharged from the coolant ejection part 50 to the first direction D1 and the coolant to flow from the coolant inlet 60 to the second direction D2, the coolant ejection part 50 and the coolant inlet 60 may have a specific shape.

The area of the coolant ejection part 50 according to the embodiment may be larger than the area of the coolant inlet 60. The area of the coolant ejection part 50 may be an area through which the coolant may flow in the coolant ejection part 50. The area of the coolant inlet 60 may be an area through which the coolant may flow in the coolant inlet 60. If the area of the coolant ejection part 50 is larger than the area of the coolant inlet 60, the pipe resistance of the coolant may be greater in the coolant inlet 60 than in the coolant ejection part 50. The pipe resistance of the coolant may be a force that acts on the coolant in the opposite direction to the flow when the coolant flows along the cooling channel 3. The pipe resistance of the coolant may be a force that interferes with the flow of the coolant. If the coolant pipe resistance is greater in the coolant inlet 60 than in the coolant ejection part 50, it is possible to prevent the coolant from flowing out from the pressure chamber 40 toward the coolant inlet 60. If the coolant pipe resistance is greater in the coolant inlet 60 than in the coolant ejection part 50, the coolant inside the pressure chamber 40 may be ejected in the direction of the coolant ejection part 50. When the area of the coolant ejection part 50 is larger than the area of the coolant inlet 60, the coolant inside the pressure chamber 40 may be ejected toward the coolant ejection part 50, if the pressure of the pressure chamber 40 increases. When the area of the coolant ejection part 50 is larger than the area of the coolant inlet 60, backflow of the coolant in the coolant inlet 60 may be reduced. The coolant flowing back from the coolant inlet 60 may be the coolant flowing in a direction opposite to the second direction D2 from the coolant inlet 60. However, the relationship between the areas of the coolant ejection part 50 and the coolant inlet 60 and the flow of the coolant is not limited to the above description.

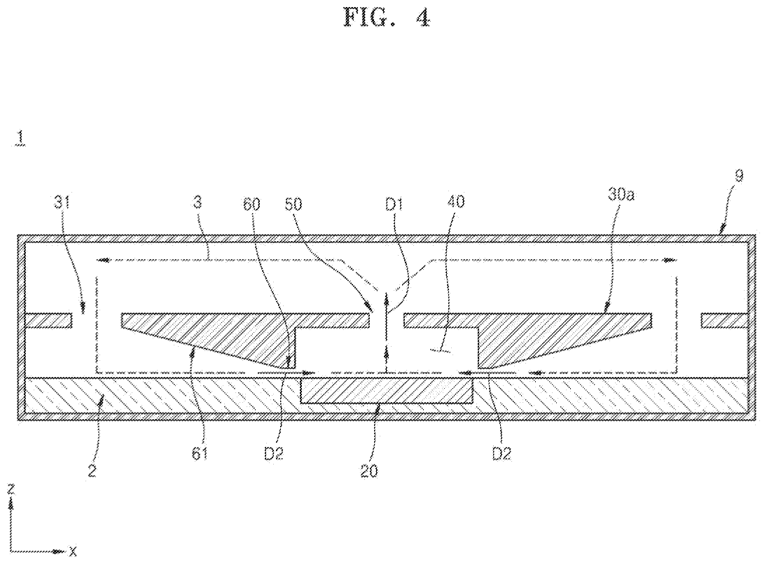

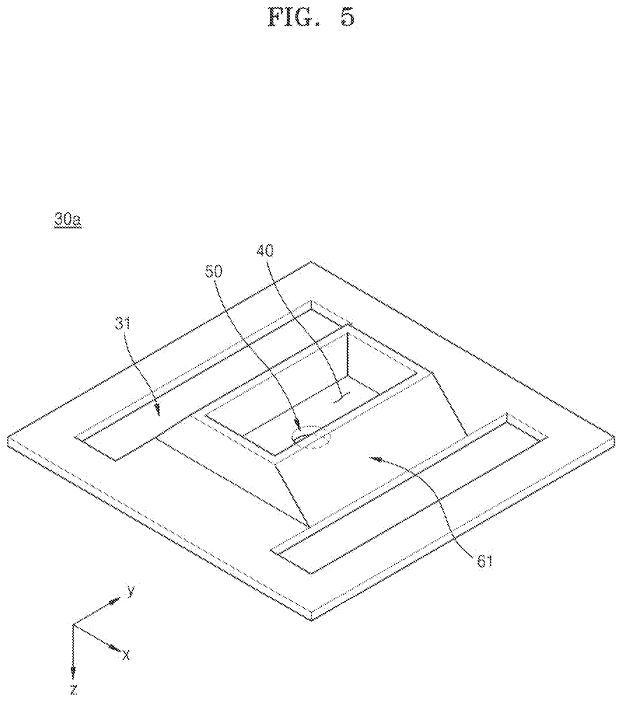

FIG. 4 is a cross-sectional view of a semiconductor device 1 according to one or more embodiments. FIG. 5 is a bottom perspective view of a channel frame 30a of the semiconductor device 1 of FIG. 4 according to one or more embodiments.

Referring to FIGS. 4 and 5, the cooling channel 3 of the semiconductor device 1 according to one or more embodiments may include an inclined structure 61. The channel frame 30a may include an inclined structure 61. The coolant inlet 60 may include the inclined structure 61. The inclined structure 61 may be a structure that induces the flow of coolant in order to let the coolant flow in the direction from the coolant inlet 60 to the pressure chamber 40. The inclined structure 61 may be a structure that induces the coolant to flow in the second direction D2 from the coolant inlet 60. The inclined structure 61 may have a structure capable of preventing the coolant from flowing back in the coolant inlet 60. The inclined structure 61 may have a structure capable of preventing the coolant from flowing back in the cooling channel 3. The coolant flowing back may be a flow of the coolant in the coolant inlet 60 in a direction opposite to the second direction D2. The coolant flowing back may be a coolant in the pressure chamber 40 flowing in a direction from the coolant inlet 60 to the outside of the pressure chamber 40. The coolant flowing back may be a coolant flowing in a direction from the coolant inlet 60 to exit the pressure chamber 40. However, the function of the inclined structure 61 is not limited to the above description.

The inclined structure 61 according to one or more embodiments may be connected to the coolant inlet 60. The inclined structure 61 may be disposed at a lower end of the channel frame 30a. The coolant may reach the coolant inlet 60 after passing through the inclined structure 61 on the cooling channel 3. The coolant may flow into the pressure chamber 40 after passing through the inclined structure 61 on the cooling channel 3. However, the arrangement of the inclined structure 61 is not limited to the above description.

The inclined structure 61 may have such a shape as being inclined toward the coolant inlet 60 on the cooling channel 3. The inclined structure 61 may have such a shape as being inclined toward the pressure chamber 40 on the cooling channel 3. The inclined structure 61 may have such a shape as a cross-sectional area through which the coolant may flow on the cooling channel 3 being narrowed. However, the shape of the inclined structure 61 is not limited to the above description.

The inclined structure 61 may exert pressure on the coolant toward the coolant inlet 60. The coolant may be compressed toward the coolant inlet 60 on the cooling channel 3 by the inclined structure 61. The coolant may be compressed in the second direction D2 on the coolant inlet 60 by the inclined structure 61. The coolant may flow in the second direction D2 on the coolant inlet 60 by the inclined structure 61. Backflow of the coolant in the coolant inlet 60 may be prevented by the inclined structure 61. The coolant may be prevented from leaking from the pressure chamber 40 by the inclined structure 61 to the coolant inlet 60. However, the relationship between the inclined structure 61 and the reverse flow of the coolant is not limited to the above description.

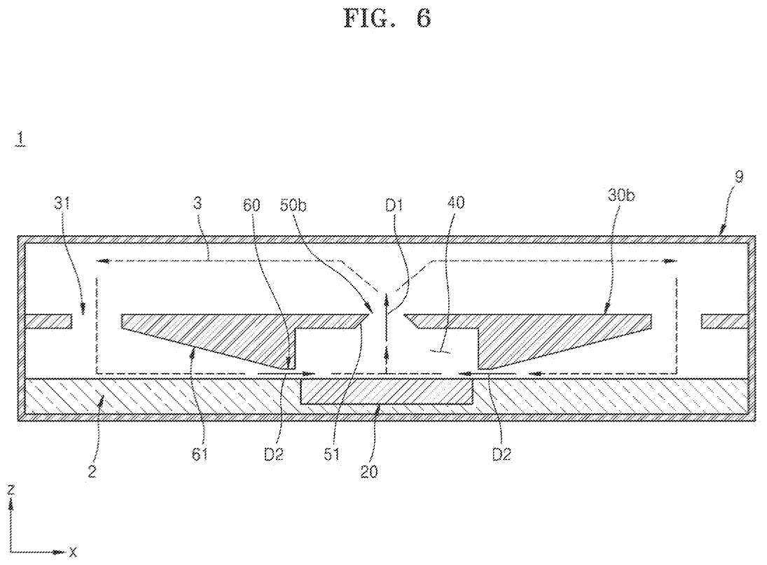

FIG. 6 is a cross-sectional view of a semiconductor device 1 according to one or more embodiments.

Referring to FIG. 6, a semiconductor device 1 according to one or more embodiments may include a coolant ejection part 50b. The coolant ejection part 50b may have a nozzle structure 51. The channel frame 30 may include a nozzle structure 51. The channel frame 30b may include a coolant ejection part 50b having a nozzle structure 51. The nozzle structure 51 may be configured such that a path through which the coolant may flow becomes narrower toward the top. The coolant ejection part 50b may include a nozzle structure 51, wherein a path allowing the coolant to flow becomes narrower toward the top. However, the structures of the channel frame 30b and the coolant ejection part 50b are not limited to the above description.

The nozzle structure 51 according to one or more embodiments may induce the coolant to be ejected from the coolant ejection part 50b. The nozzle structure 51 may induce the ejection of the coolant so that the coolant may be well ejected from the pressure chamber 40. The nozzle structure 51 may increase the flow rate of the coolant. When the pressure decreases as the coolant is ejected from the coolant ejection part 50b, the nozzle structure 51 may increase the flow rate of the coolant. The nozzle structure 51 can induce the flow of coolant so that the coolant ejected from the coolant ejection part 50b can flow rapidly on the cooling channel 3. The nozzle structure 51 may induce the flow of coolant on the cooling channel 3. However, the function of the nozzle structure 51 is not limited to the above description.

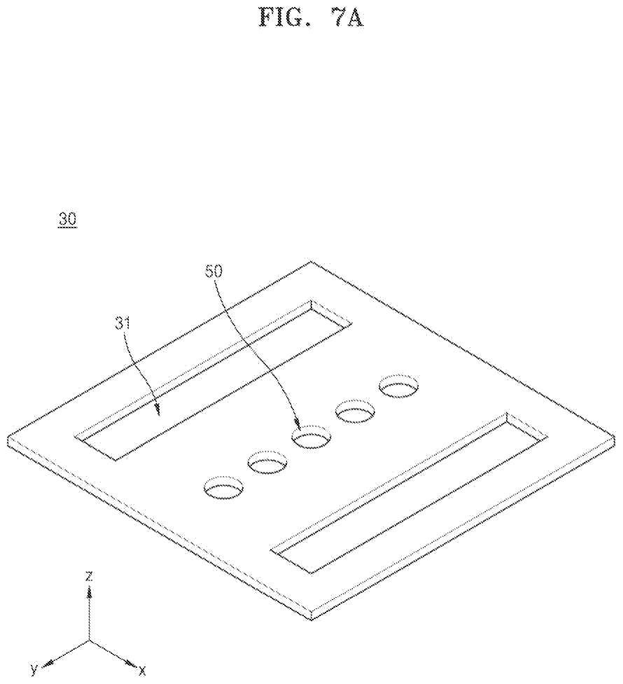

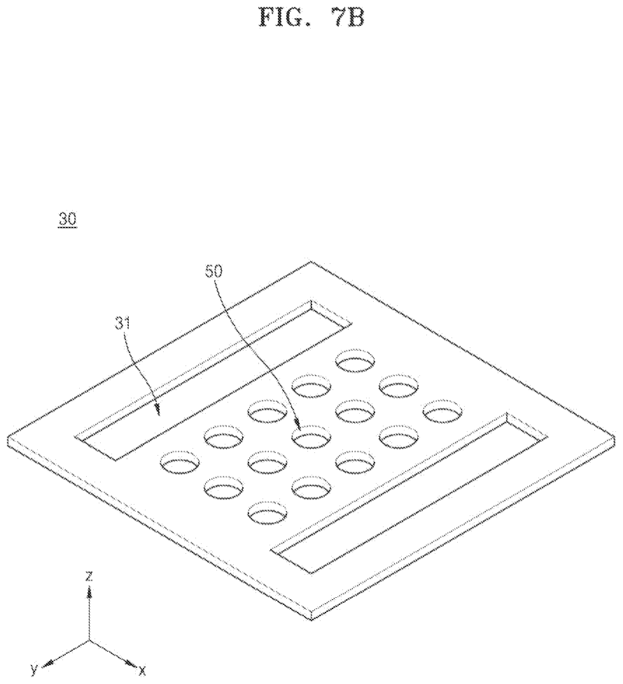

FIG. 7A is a top perspective view of a channel frame 30 according to one or more embodiments. FIG. 7B is a top perspective view of a channel frame 30 according to one or more embodiments.

Referring to FIGS. 6 to 7B, a semiconductor device 1 according to one or more embodiments may include a plurality of coolant ejection parts 50. The cooling channel 3 may include a plurality of coolant ejection parts 50. The channel frame 30 may include a plurality of coolant ejection parts 50.

A plurality of coolant ejection parts 50 according to one or more embodiments may be disposed side by side. A plurality of coolant ejection parts 50 may be arranged in a row. A plurality of coolant ejection parts 50 may be arranged in a row in a direction parallel to the y-axis. The plurality of coolant ejection parts 50 arranged in a row may be disposed at predetermined intervals in the direction of the coolant circulation part 31. The plurality of coolant ejection parts 50 arranged in a row may be disposed at predetermined intervals in a direction parallel to the x-axis. In other words, a plurality of coolant ejection parts 50 may be disposed on the cooling channel 3 to be spaced apart from each other in the x-axis or y-axis direction. However, the arrangement of the plurality of coolant ejection parts 50 is not limited to the above description.

The pressure chamber 40 according to one or more embodiments may include a plurality of coolant ejection parts 50. The semiconductor device 1 may include a plurality of pressure chambers 40. Each of the plurality of coolant ejection parts 50 may correspond to each one of the pressure chambers 40. Each of the plurality of pressure chambers 40 may include several coolant ejection parts 50. However, the above description with regard to the relationship between the pressure chamber 40 and the coolant ejection part 50 is only an exemplary description and is not limited thereto.

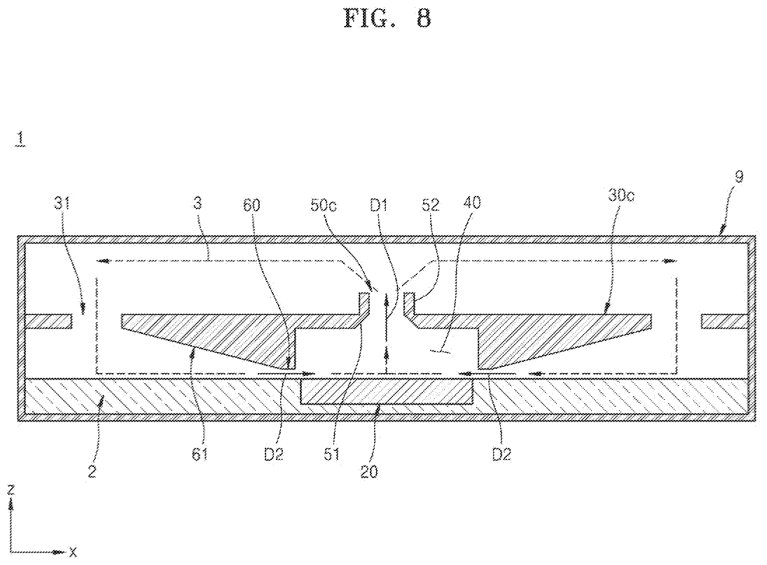

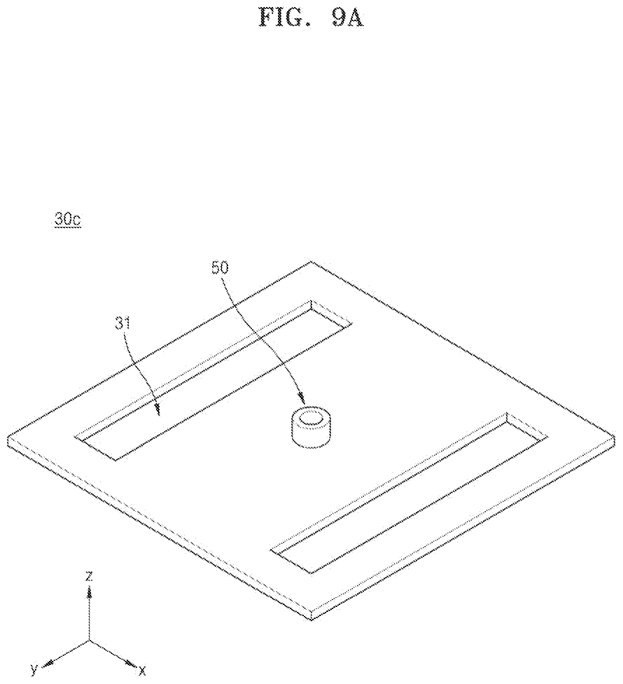

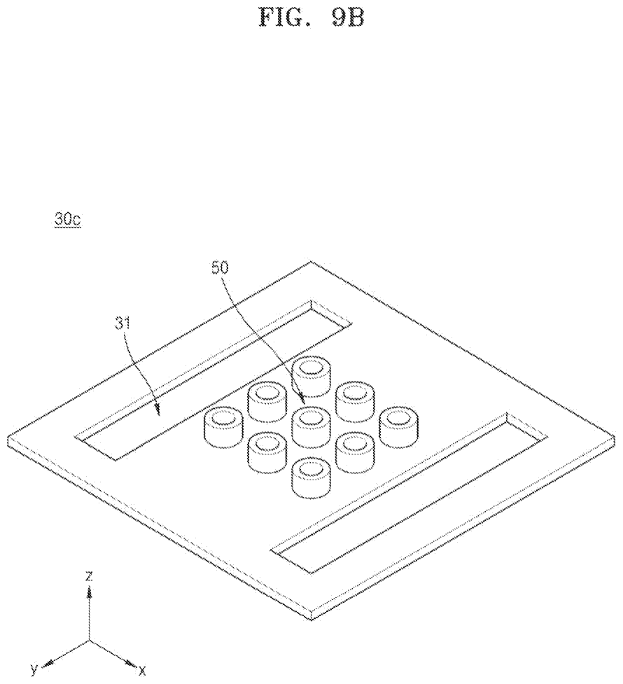

FIG. 8 is a cross-sectional view of a semiconductor device 1 according to one or more embodiments. FIG. 9A is a top perspective view of a channel frame 30 according to one or more embodiments. FIG. 9B is a top perspective view of a channel frame 30 according to one or more embodiments.

Referring to FIGS. 8 to 9B, the coolant ejection part 50c according to one or more embodiments may include a protruding structure 52. The coolant ejection part 50c may include a protruding structure 52 protruding in the first direction D1. The channel frame 30c may include a protruding structure 52. The protruding structure 52 may guide a path along which the coolant is ejected from the coolant ejection part 50c. The protruding structure 52 may induce the ejection direction of the coolant in order to let the coolant be ejected from the coolant ejection part 50c in the first direction D1. The protruding structure 52 may prevent the coolant ejected from the coolant ejection part 50c from flowing back into the pressure chamber 40. The protruding structure 52 may prevent the coolant from flowing back from the coolant ejection part 50c. However, the function of the protruding structure 52 is not limited to the above description.

A plurality of coolant ejection parts 50c according to one or more embodiments may be provided. Each of the plurality of coolant ejection parts 50c may include a protruding structure 52. However, the protruding structure 52 of the plurality of coolant ejection parts 50c is not limited to the above description. For example, only a part of a plurality of coolant ejection parts 50c may include the protruding structure 52.

A plurality of the coolant ejection parts 50c according to one or more embodiments may be disposed above a single pressure chamber 40. Each of the plural coolant ejection parts 50c may be disposed on each of the plural pressure chambers 40. However, this is only an exemplary description and is not limited thereto.

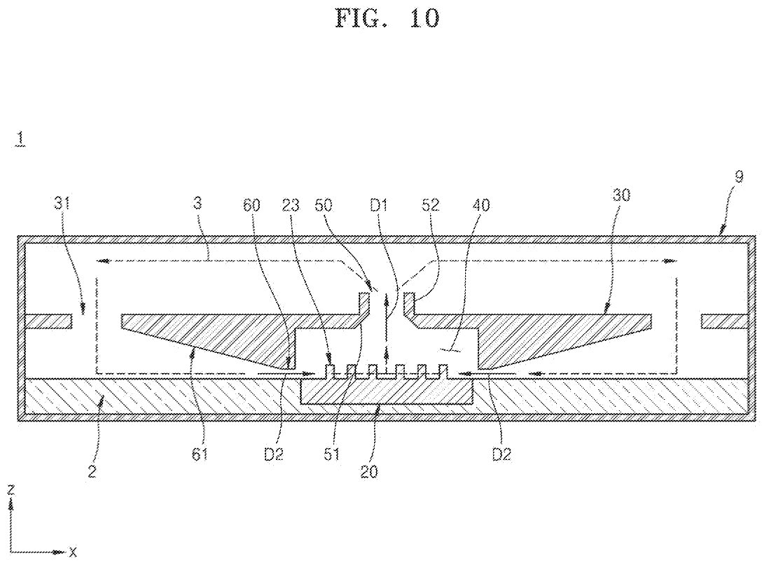

FIG. 10 is a cross-sectional view of a semiconductor device 1 according to one or more embodiments.

Referring to FIG. 10, a semiconductor chip 2 according to one or more embodiments may be formed with a fine pattern 23 on at least a portion of a surface thereof. The heat radiation part 20 may be formed with the fine pattern 23 on at least a part of the surface. The fine pattern 23 may be a wick pattern. The fine pattern 23 may be the pattern wherein a plurality of microstructures are formed with predetermined intervals. The fine pattern 23 may be a pattern wherein a plurality of fine protrusions are formed with predetermined intervals. The fine pattern 23 may be a pattern wherein a plurality of fine pillars are formed with predetermined intervals. It may be a pattern formed with predetermined intervals. The fine pattern 23 may form a capillary pressure, which causes the coolant to flow. The fine pattern 23 may cause the coolant to flow in a direction toward the center of the pressure chamber 40. The fine pattern 23 may be configured to cause the coolant flow in the second direction D2. However, the shape and the function of the fine pattern 23 are not limited to the above description.

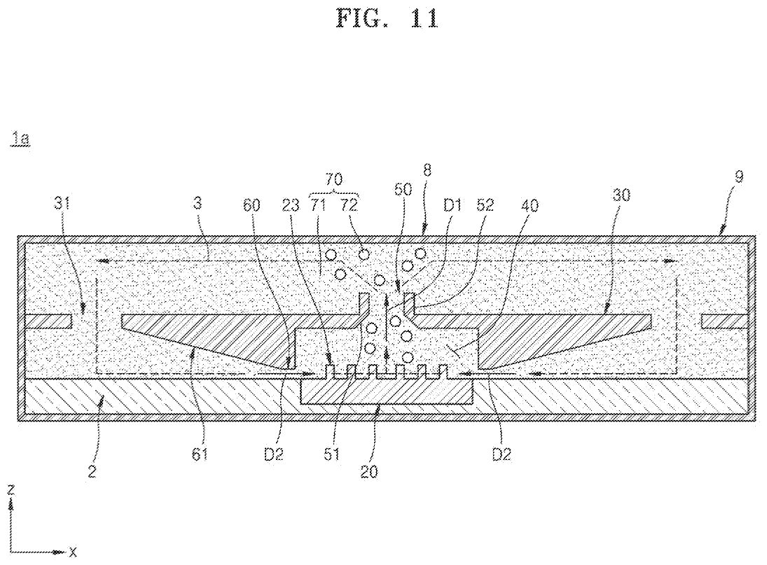

FIG. 11 is a cross-sectional view of the semiconductor device 1 according to one or more embodiments.

Referring to FIG. 11, a semiconductor device 1 according to one or more embodiments may include liquid coolant 71. The liquid coolant 71 may be disposed inside the semiconductor device 1. The liquid coolant 71 may be disposed on the semiconductor chip 2. The liquid coolant 71 may be disposed on the heat radiation part 20. The liquid coolant 71 may be disposed on the cooling channel 3. However, the arrangement of the liquid coolant 71 is not limited to the above description.

The liquid coolant 71 according to one or more embodiments may fill the inside of the semiconductor device 1. The liquid coolant 71 may fill the inside of the pressure chamber 40. Filling of the inside of the pressure chamber 40 with the liquid coolant 71 may be the filling of the inside of the pressure chamber 40 with the volume of the liquid coolant 71. However, the volume of the liquid coolant 71 is not limited to the above description.

The liquid coolant 71 may cool the semiconductor chip 2. The liquid coolant 71 may absorb heat generated during the operation of the semiconductor chip 2. The liquid coolant 71 may absorb heat radiated by the heat radiation part 20. The liquid coolant 71 may cool the heat radiation part 20. However, the function of the liquid coolant 71 is not limited to the above description.

The semiconductor device 1 according to one or more embodiments may include gaseous coolant 72. The liquid coolant 71 may be converted into the gaseous coolant 72 through phase change. The liquid coolant 71 may absorb heat generated from the semiconductor chip 2 to thereby change a phase into the gaseous coolant 72. The liquid coolant 71 may absorb heat radiated from the heat radiation part 20 to thereby change a phase into the gaseous coolant 72. The liquid coolant 71 may cool the semiconductor chip 2 using the heat absorbed when the phase changes into the gaseous coolant 72. The structure for cooling the semiconductor chip 2 using the coolant 70 may be a two phase liquid cooling structure. A system for cooling the semiconductor chip 2 using the coolant 70 may be two phases liquid cooling system. However, the principle of cooling the semiconductor chip 2 by the liquid coolant 71 and the gaseous coolant 72 is not limited to the above description.

The liquid coolant 71 may be phase-changed into the gaseous coolant 72 in the pressure chamber 40. Volume per unit mass of the liquid coolant 71 may be greater than the volume per unit mass of the gaseous coolant. When the liquid coolant 71 in the pressure chamber 40 changes the phase into the gaseous coolant 72, the pressure in the pressure chamber 40 may increase. The liquid coolant 71 can increase the internal pressure of the pressure chamber 40 by changing the phase to the gaseous coolant 72 as the liquid coolant 71 absorbs heat from the heat radiation part 20.

When the pressure inside the pressure chamber 40 increases, the coolant 70 may be ejected into the coolant ejection part 50. When the pressure inside the pressure chamber 40 increases, the coolant 70 may be ejected from the coolant ejection part 50 in a direction away from the heat radiation part 20. When the pressure inside the pressure chamber 40 increases, the coolant 70 may be ejected from the coolant ejection part 50 in the first direction D1. The coolant 70 ejected from the coolant ejection part 50 may be the liquid coolant 71. The coolant 70 ejected from the coolant ejection part 50 may be the gaseous coolant 72. The coolant 70 ejected from the coolant ejection part 50 may include both the liquid coolant 71 and the gaseous coolant 72. However, the coolant 70 ejected from the liquid ejection part is not limited to the above description.

In the semiconductor device 1 according to one or more embodiments, the coolant 70 may circulate through the cooling channel 3. The coolant 70 may be circulated by the coolant 70 ejected from the coolant ejection part 50. The circulation of the coolant 70 in the cooling channel 3 may be due to the force caused by the coolant ejection part 50 ejecting the coolant 70. However, the relationship between the coolant ejection part 50 and the circulation of the coolant 70 is not limited to the above description.

Meanwhile, the liquid coolant 71 may be phase-changed into the gaseous coolant 72 on the surface of the heat radiation part 20. The gaseous coolant 72 may flow from the surface of the heat radiation part 20 to the coolant ejection part 50. When the gaseous coolant 72 moves from the surface of the heat radiation part 20 to the coolant ejection part 50, the liquid coolant 71 may fill an empty space. However, the position at which the liquid coolant 71 is phase-changed to the gaseous coolant 72 is not limited to the above description.

The fine pattern 23 according to one or more embodiments may form a capillary pressure causing the coolant 70 to flow. The fine pattern 23 may apply capillary pressure to the liquid coolant 71. The capillary pressure may exert force causing the liquid coolant 71 to flow to let the liquid coolant 71 fill a space between the fine patterns 23. When the liquid coolant 71 fills the space between the fine patterns 23, an area in which the liquid coolant 71 contacts the surface of the heat radiation part 20 may be large. If the liquid coolant 71 has a large area in contact with the surface of the heat radiation part 20, the speed at which the liquid coolant 71 changes the phase to the gaseous coolant 72 may be increased. When an area in which the liquid coolant 71 contacts the surface of the heat radiation part 20 is large, cooling efficiency of the heat radiation part 20 may be high. However, the relationship between the fine pattern 23 and the cooling efficiency of the heat radiation part 20 is not limited to the above description.

On the other hand, if the liquid coolant 71 flows in the direction toward the center of the pressure chamber 40, the process of phase change from the liquid coolant 71 into the gaseous coolant 72 may be promoted. If the liquid coolant 71 flows in the pressure chamber 40 toward the center of the pressure chamber 40, the process of phase change from the liquid coolant 71 into the gaseous coolant 72 may be promoted. The promotion of the process of phase change from liquid coolant 71 to gaseous coolant 72 may result in a large amount of liquid coolant 71 that changes phase to gaseous coolant 72 per unit time.

The fine pattern 23 according to one or more embodiments may cause the coolant 70 to flow in a direction toward the center of the pressure chamber 40. The surface of the heat radiation part 20 may include hydrophobic material and hydrophilic material. The fine pattern 23 may include the hydrophobic material and the hydrophilic material. The surface of the heat radiation part 20 adjacent to the coolant inlet 60 may include the hydrophobic material. The surface of the heat radiation part 20 adjacent to the center of the pressure chamber 40 may include the hydrophilic material. The fine pattern 23 adjacent to the coolant inlet 60 may include the hydrophobic material. The fine pattern 23 adjacent to the center of the pressure chamber 40 may include the hydrophilic material. The hydrophilic material may be the material that has a higher bonding force with the liquid coolant 71. The hydrophobic material may be the material that has a lower bonding force with the liquid coolant 71. The liquid coolant 71 may receive the force to flow from the hydrophobic material to the hydrophilic material. The liquid coolant 71 may receive the force to flow in the direction toward the center of the pressure chamber 40. The direction toward the center of the pressure chamber 40 may be a second direction D2. However, the force received by the liquid coolant 71 is not limited to the above description.

Meanwhile, the semiconductor device 1 may include a condensing unit 8. The condensing unit 8 may exchange heat with the coolant 70. The coolant 70 may transfer heat to the condensing unit 8. The gaseous coolant 72 may transfer heat to the condensing unit 8. The condensing unit 8 may cool the gaseous coolant 72. The condensing unit 8 may cool the gaseous coolant 72 to change a phase into the liquid coolant 71. The condensing unit 8 may be the part that changes phase from the gaseous coolant 72 to the liquid coolant 71. The condensing unit 8 may be disposed at an upper part of the semiconductor device 1. The condensing unit 8 may be disposed above the coolant ejection part 50. The condensing unit 8 may be disposed on the housing 9. The condensing unit 8 may be the part where the cooling channel 3 is in contact with the housing 9. The condensing unit 8 may be a part where the coolant 70 is in contact with the housing 9. However, the arrangement and the function of the condensing unit 8 are not limited to the above description.

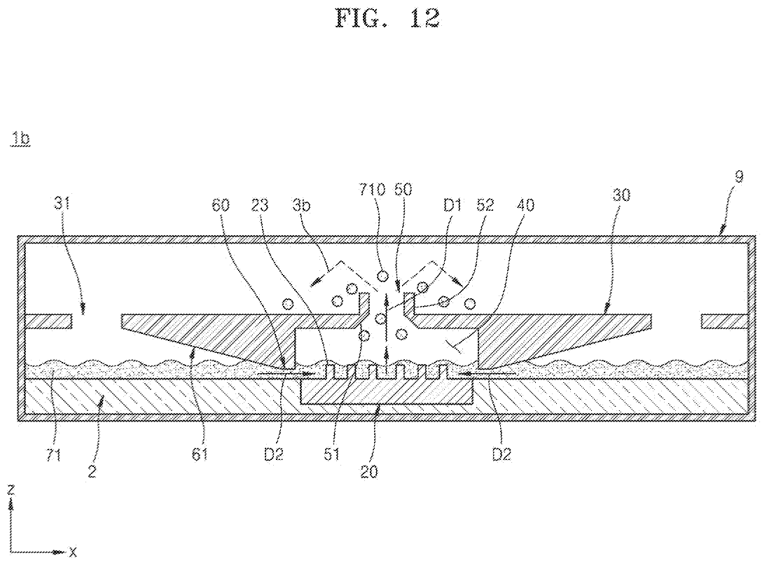

FIG. 12 is a cross-sectional view of a semiconductor device 1 according to one or more embodiments.

Referring to FIG. 12, the liquid coolant 71 included in the semiconductor device 1 according to one or more embodiments may cover the surface of the heat radiation part 20. The liquid coolant 71 may be disposed from the surface of the heat radiation part 20 to at least the upper end of the coolant inlet 60. The volume of the liquid coolant 71 may fill the interior of the pressure chamber 40 from the heat radiation part 20 to at least the upper end of the coolant inlet 60 (i.e. an end of the coolant inlet 60 furthest from the heat radiation part 20 in the first direction D1). If the volume of the liquid coolant 71 can fill the interior of the pressure chamber 40 from the heat radiation part 20 to at least the upper end of the coolant inlet 60, the liquid coolant 71 can fill the coolant inlet 60. However, the volume of the liquid coolant 71 is not limited to the above description.

The liquid coolant 71 according to one or more embodiments may be disposed from the surface of the heat radiation part 20 to the height below the coolant ejection part 50. The liquid coolant 71 may be disposed from the surface of the heat radiation part 20 to a height that does not fill the coolant ejecting part 50. The liquid coolant 71 may be disposed from the surface of the heat radiation part 20 to the height below the coolant ejection part 50. The liquid coolant 71 being disposed at the height below the coolant ejection part 50 may mean that the level of the liquid coolant 71 does not reach the coolant ejection part 50. However, the height at which the level of the liquid coolant 71 is placed is not limited to the above description.

On the other hand, when the heat radiation part 20 transfers heat to the liquid coolant 71, droplets may be generated on the surface of the liquid coolant 71 in the pressure chamber 40. The surface of the liquid coolant 71 may be defined by the level of the liquid coolant 71 in the pressure chamber 40. The droplet 710 produced on the surface of the liquid coolant 71 may be produced by a volume that changes when the liquid coolant 71 changes phase to the gaseous coolant 72 in the pressure chamber 40. The droplet 710 produced on the surface of the liquid coolant 71 may be due to the kinetic energy transmitted from the gaseous coolant 72 to the liquid coolant 71. However, the droplet 710 produced on the surface of the liquid coolant 71 is not limited to the above description.

The droplets generated on the surface of the liquid coolant 71 according to one or more embodiments may splash upward from the surface of the liquid coolant 71. The droplets splashing from the surface of the liquid coolant 71 may move in the first direction D1. The droplets 710 splashing from the surface of the liquid coolant 71 may reach the coolant ejection part 50. The droplets 710 splashing from the surface of the liquid coolant 71 may be ejected to the outside of the pressure chamber 40 through the coolant ejection part 50. The droplet 710 may be ejected to the outside of the pressure chamber 40 through the ejection path 3b. The droplet 710 ejected to the outside of the pressure chamber 40 through the coolant ejection part 50 may move from the outside of the pressure chamber 40 to the coolant circulation part 31. However, the movement of the droplets 710 produced on the surface of the liquid coolant 71 is not limited to the above description.

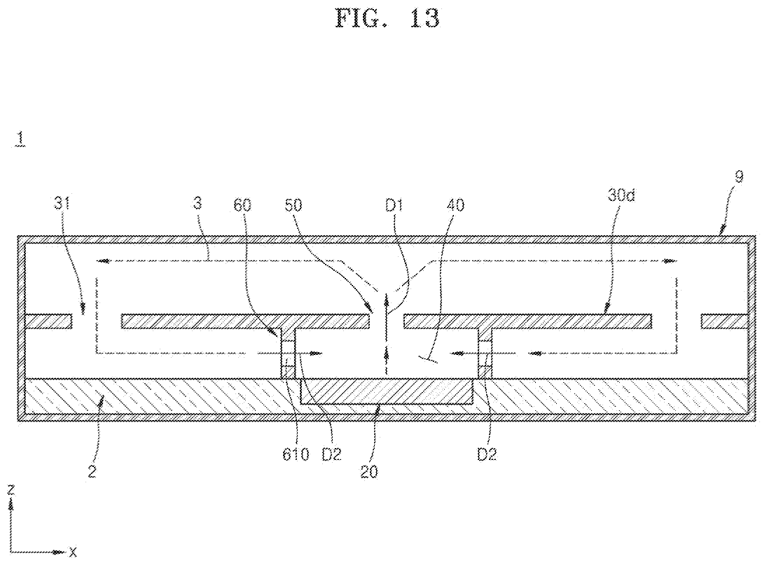

FIG. 13 is a cross-sectional view of a semiconductor device 1 according to one or more embodiments.

Referring to FIG. 13, the semiconductor device 1 according to the embodiment may include a backflow prevention structure 610. The backflow prevention structure 610 may be disposed on the cooling channel 3. The backflow prevention structure 610 may be disposed on the coolant inlet 60. The backflow prevention structure 610 may prevent backflow of the coolant 70 on the cooling channel 3. The backflow prevention structure 610 may prevent backflow of the coolant 70 on the coolant inlet 60. The backflow prevention structure 610 may induce the coolant 70 to move in the second direction D2 on the coolant inlet 60. The backflow prevention structure 610 can induce the coolant 70 to move in the direction toward the pressure chamber 40 on the cooling channel 3. However, the function and the arrangement of the backflow prevention structure 610 are not limited to the above description.

The backflow prevention structure 610 according to one or more embodiments may open and close the coolant inlet 60. The backflow prevention structure 610 may open and close the coolant inlet 60. Opening the coolant inlet 60 may provide a flow path for the coolant 70 in order to enable the coolant 70 to flow through the coolant inlet 60. Closing the coolant inlet 60 may prevent the coolant 70 from flowing through the coolant inlet 60. In other words, the backflow prevention structure 610 may prevent the coolant from exiting the pressure chamber 40 through the coolant inlet 60. However, the relationship between the backflow prevention structure 610 and the flow of the coolant 70 is not limited to the above description.

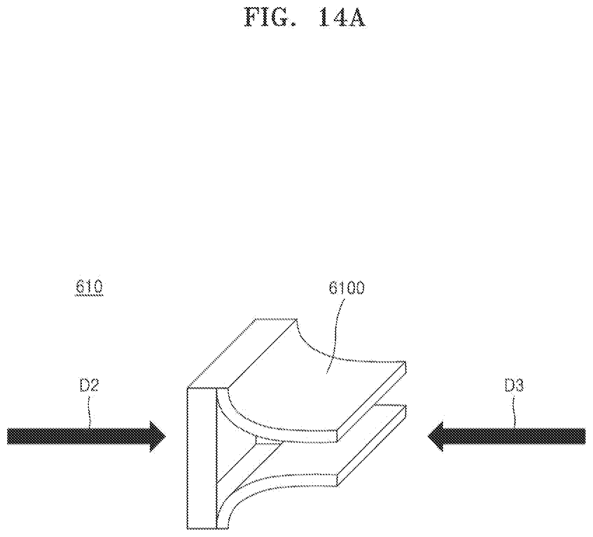

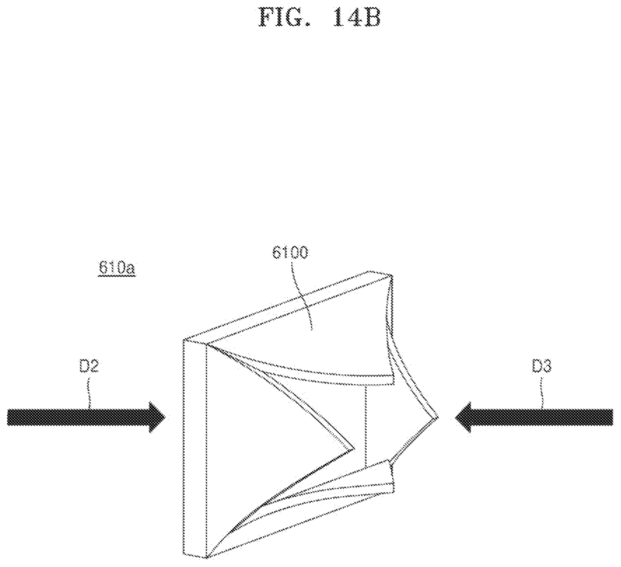

FIG. 14A is a perspective view of a backflow prevention structure 610 according to one or more embodiments. FIG. 14B is a perspective view of a backflow prevention structure 610 according to one or more embodiments.

Referring to FIGS. 13 to 14B, the backflow prevention structure 610 according to one or more embodiments may include a flap valve. The flap valve may open and close the coolant inlet 60. The flap valve may open and close the coolant inlet 60.

The backflow prevention structure 610 according to one or more embodiments may selectively open and close the coolant inlet 60 according to the direction in which the coolant 70 flows. The flap valve of the backflow prevention structure 610 can open the coolant inlet 60 when the coolant 70 through the coolant inlet 60 flows in the direction toward the pressure chamber 40. When the coolant 70 on the coolant inlet 60 flows from the pressure chamber 40 in the direction toward the coolant inlet 60, the flap valve of the backflow prevention structure 610 may close the coolant inlet 60. The flap valve of the backflow prevention structure 610 may open the coolant inlet 60 when the coolant 70 flows in the second direction D2. The flap valve of the backflow prevention structure 610 may close the coolant inlet 60 when the coolant 70 flows in the third direction D3. The third direction D3 may be a direction toward the coolant inlet 60 inside the pressure chamber 40. The third direction D3 may be the direction opposite to the second direction D2. However, the relationship between the opening and closing of the coolant inlet 60 and the flow direction of the coolant 70 is not limited to the above description.

The flap valve according to one or more embodiments may be provided in plural (i.e. more than one). The flap valve may include flexible material. The flap valve may be configured to be bent according to the flow of the coolant 70. The flap valve may open and close the coolant inlet 60 by being bent according to the flow of the coolant 70. The flap valve may open and close the coolant inlet 60 according to the flow direction of the coolant 70 flowing through the coolant inlet 60. The flap valve may restrict the flow direction of the coolant 70 by opening and closing the coolant inlet 60 according to the flow direction of the coolant 70. The flap valve may open and close the coolant inlet 60 in order not to allow the coolant 70 to flow in a third direction D3 at the coolant inlet 60.

While certain embodiments of the disclosure has been particularly shown and described, it will be understood that various changes in form and details may be made therein without departing from the spirit and scope of the following claims.

What is claimed is:

1. A semiconductor device comprising:
a semiconductor chip comprising a heat radiation part;
a pressure chamber formed on the heat radiation part, wherein the pressure chamber is configured to contain coolant such that an internal pressure in the pressure chamber increases as the coolant absorbs heat from the heat radiation part, and the coolant is ejected in a first direction away from the heat radiation part as the internal pressure of the pressure chamber increases; and
a cooling channel providing a flow path configured such that the coolant ejected from the pressure chamber flows through the flow path and back into the pressure chamber.

2. The semiconductor device of claim 1, wherein the pressure chamber comprises a coolant ejection part and a coolant inlet that define at least a part of the cooling channel.

3. The semiconductor device of claim 2, wherein the cooling channel is configured to connect the coolant ejection part and the coolant inlet to each other to enable the coolant to circulate within the semiconductor device.

4. The semiconductor device of claim 2, wherein the coolant ejection part is configured to eject the coolant in a direction perpendicular to the semiconductor chip.

5. The semiconductor device of claim 2, wherein the coolant ejection part is disposed on an end of the pressure chamber furthest from the heat radiation part in the first direction.

6. The semiconductor device of claim 5, wherein the coolant ejection part comprises a nozzle structure configured to induce the coolant to flow away from the heat radiation part in the first direction and to be ejected from the pressure chamber.

7. The semiconductor device of claim 5, wherein the coolant ejection part comprises a protruding structure protruding in the first direction.

8. The semiconductor device of claim 2, wherein the coolant ejection part comprises two or more coolant ejection parts.

9. The semiconductor device of claim 3, wherein an area where the coolant flows in the coolant ejection part is larger than an area where the coolant flows in the coolant inlet.

10. The semiconductor device of claim 3, wherein the coolant inlet is arranged to allow the coolant to be introduced in a second direction crossing the first direction.

11. The semiconductor device of claim 3, wherein the coolant is ejected in the first direction from a lower part to an upper part of the pressure chamber, and
wherein the coolant inlet is disposed on the lower part of a side of the pressure chamber.

12. The semiconductor device of claim 11, wherein the cooling channel comprises an inclined structure connected to the coolant inlet.

13. The semiconductor device of claim 11, wherein the cooling channel comprises a backflow prevention structure configured to prevent the coolant from exiting the pressure chamber through the coolant inlet.

14. The semiconductor device of claim 13, wherein the backflow prevention structure comprises a flap valve configured to enable opening and closing of the coolant inlet.

15. The semiconductor device of claim 2, further comprising:
a liquid coolant for cooling the semiconductor chip,
wherein a volume of the liquid coolant fills a space from at least the heat radiation part to an end of the coolant inlet furthest from the heat radiation part in the first direction within the pressure chamber.

16. The semiconductor device of claim 15, wherein the volume of the liquid coolant fills at least an inside of the pressure chamber.

17. The semiconductor device of claim 15, wherein the liquid coolant is configured to increase the internal pressure in the pressure chamber by changing a phase of the liquid coolant into a gaseous phase as the heat radiation part absorbs heat.

18. The semiconductor device of claim 17, wherein the coolant ejection part is configured to eject gaseous coolant as the internal pressure of the pressure chamber increases.

19. The semiconductor device of claim 2, wherein the heat radiation part comprises a fine pattern configured to generate a capillary pressure causing a flow of the coolant on at least a part of a surface of the heat radiation part.

20. The semiconductor device of claim 19, wherein the fine pattern is configured to induce the flow of the coolant toward a center of the pressure chamber.
